(19) United States
(12) Patent Application Publication
(10) Pub. No.: US 2026/0072856 A1
(43) Pub. Date: Mar. 12, 2026

(54) CONFIGURABLE MEMORY DEVICE

(71) Applicant: Rambus Inc., San Jose, CA (US)

(72) Inventor: Torsten PARTSCH, Raleigh, NC (US)

(21) Appl. No.: 19/106,370

(22) PCT Filed: Aug. 22, 2023
(86) PCT No.: PCT/US23/30861

§ 371 Date: Feb. 25, 2025

Related U.S. Application Data
(60) Provisional application No. 63/403,103, filed on Sep. 1, 2022.

(51) Int. Cl. G06F 13/16; G06F 13/28

(52) U.S. Cl. CPC G06F 13/1678; G06F 13/1689; G06F 13/287

(57) ABSTRACT

A memory device may be accessed via multiple channels (e.g., 2 channels, 4 channels, etc.). The data widths (i.e., number of data signals) allocated to each channel are configurable such that a given group of data input/output (I/O) signals may be part of a first channel in one configuration, but be part of another channel in a different configuration. Similarly, the memory arrays (e.g., banks, or bank groups) accessed by a given channel may be configurable such that a given memory array is accessed via a first channel in one configuration but is accessed via a different channel in a different configuration. Finally, the data burst length, data burst size, and data transfer clock cycle are configurable.

### BRIEF DESCRIPTION OF THE DRAWINGS

FIGS. 1A-1B are a block diagrams illustrating systems with a configurable memory device.

FIGS. 2A-2B are a block diagrams illustrating memory configurations.

FIG. 3 is a block diagram illustrating an example system configuration with four channel configurable memory devices.

FIGS. 4A-4B are diagrams illustrating example data burst configurations for multi-channel memory devices.

FIG. 5 is a block diagram illustrating a multi-channel memory device.

FIG. 6 is a flowchart illustrating a method of operating a memory device.

FIG. 7 is a flowchart illustrating a method of accessing a multi-channel memory device.

FIG. 8 is a flowchart illustrating a method of reconfiguring a multi-channel memory device.

FIG. 9 is a block diagram of a processing system.

### DETAILED DESCRIPTION OF THE EMBODIMENTS

In an embodiment, a memory device may be accessed via multiple channels (e.g., 2 channels, 4 channels, etc.). The data widths (i.e., number of data signals) allocated to each channel are configurable such that a given group of data input/output (I/O) signals may be part of a first channel in one configuration but be part of another channel in a different configuration.

Similarly, the memory arrays (e.g., banks, or bank groups) accessed by a given channel may be configurable such that a given memory array is accessed via a first channel in one configuration but is accessed via a different channel in a different configuration. Finally, the data burst length and data burst size are configurable such that, for example, a channel configured to have 32 data signals can communicate using 64 byte bursts over 16 unit intervals while a different channel (e.g., on the same memory device) configured to have 4 data signals can communicate using 16 byte bursts over 32 unit intervals.

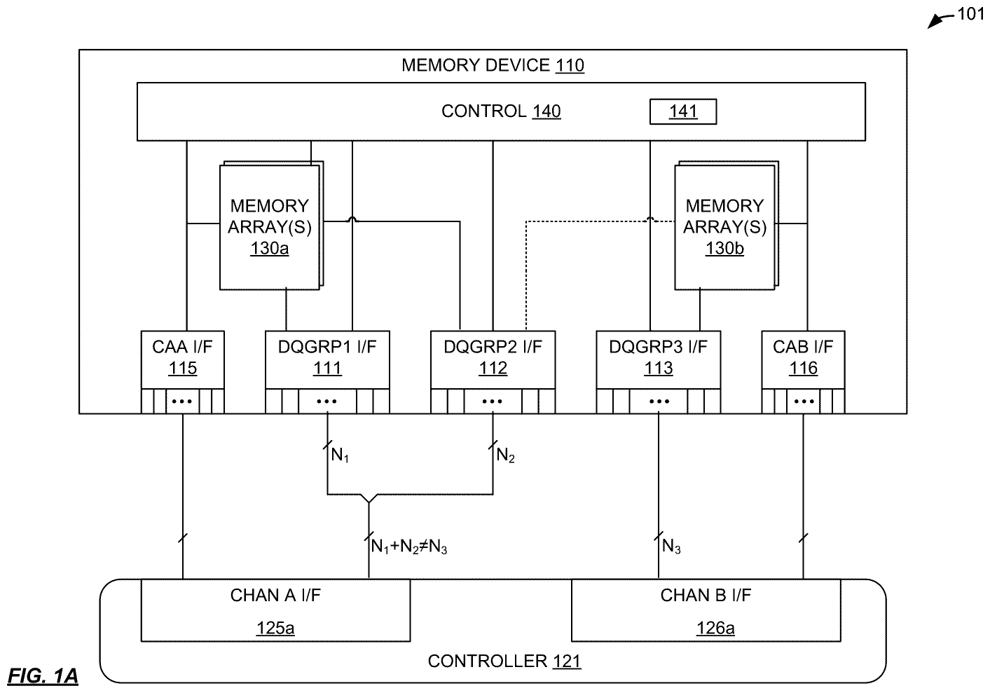

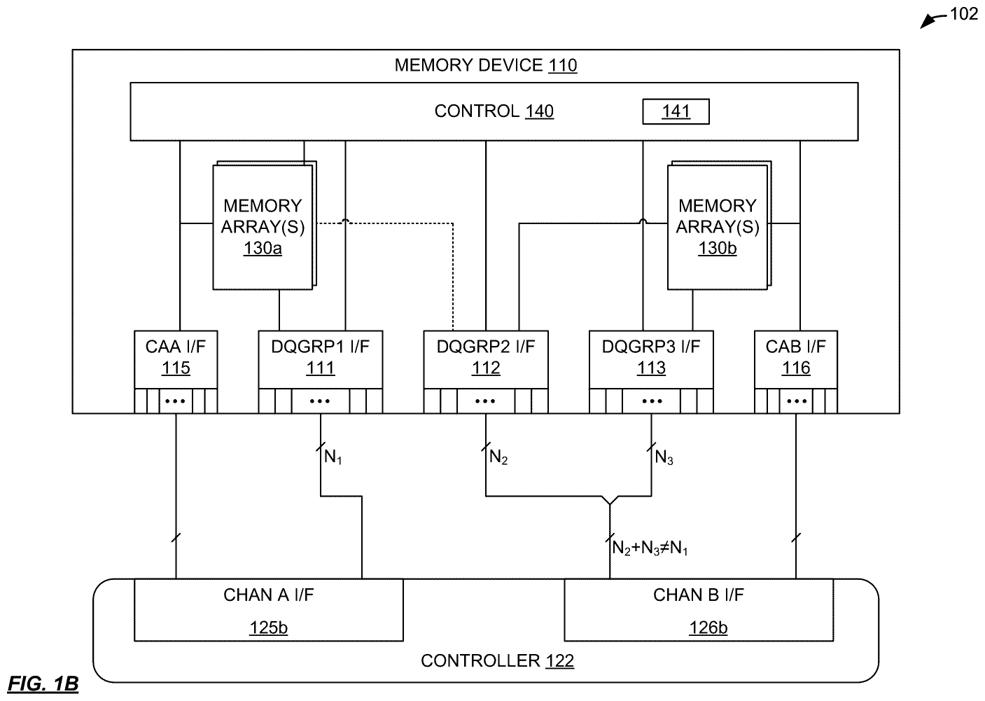

FIGS. 1A-1B are a block diagrams illustrating systems with a configurable memory device. In FIG. 1A, memory system 101 comprises memory device 110 and controller 121. Controller 121 includes two memory channel interfaces: memory channel “A” interface 125a and memory channel “B” interface 126a. In FIG. 1B, memory system 102 comprises memory device 110 and controller 122. Controller 122 includes two memory channel interfaces: memory channel “A”interface 125b and memory channel “B”interface 126b.

Memory device 110 includes data (DQ) signal group #1 interface (DQGRP1 I/F 111), DQ signal group #2 interface (DQGRP2 I/F 112), DQ signal group #3 interface (DQGRP3 I/F 113), memory channel “A” command/address interface (CAA I/F 115), memory channel “B” command/address interface (CAB I/F 116), memory arrays 130a-130b, and control circuitry 140. Control circuitry 140 includes mode/configuration circuitry 141.

CAA interface 115 of memory device 110 is operatively coupled to control circuitry 140 and memory array 130a. CAB interface 116 of memory device 110 is operatively coupled to control circuitry 140 and memory array 130b. DQGRP1 interface 111 is operatively coupled to memory array 130a and control circuitry 140. DQGRP2 interface 112 is operatively coupled to control circuitry 140. In an embodiment, DQGRP1 interface 111 has N₁ number of bidirectional DQ signals; DQGRP2 interface 112 has N₂ number of bidirectional DQ signals; and DQGRP3 interface 113 has N₃ number of bidirectional DQ signals.

Controller 121, controller 122, and memory device 110 are integrated circuit type devices, such as those commonly referred to as “chips”. A memory controller, such as controller 121 and controller 122, manages the flow of data going to and from memory devices.

Functionality of a memory controller may be included on a single die with a microprocessor, or included as part of a more complex integrated circuit system as a block of a system on a chip (SOC). For example, a memory controller may be a northbridge chip, an application specific integrated circuit (ASIC) device, a load-reduction memory buffer, a graphics processor unit (GPU), a system-on-chip (SoC) or an integrated circuit device that includes many circuit blocks such as ones selected from graphics cores, processor cores, and MPEG encoder/decoders, etc.

In memory system 101 (as illustrated in FIG. 1A), memory device 110 is in a first configuration (e.g., configured by mode/configuration circuitry 141) where DQGRP2 112 functions as part of the memory channel receiving commands/addresses via CAA interface 115 and communicating data with memory array(s) 130a. Thus, in FIG. 1A, channel A interface 125a of controller 121 is operatively coupled to CAA interface 115, DQGRP1 interface 111, and DQGRP2 interface 112. Channel B interface 126a of controller 121 is operatively coupled to CAB interface 116 and DQGRP3 interface 113. In FIG. 1A, channel A interface 125a of controller 121 has N₁+N₂ number of bidirectional data signals and channel B interface 126a of controller 121 has N₃ number of bidirectional data signals.

In memory system 102 (as illustrated in FIG. 1B), memory device 110 is in a second configuration (e.g., configured by mode/configuration circuitry 141) where DQGRP2 112 functions as part of the memory channel receiving commands/addresses via CAB interface 116 and communicating data with memory array(s) 130b. Thus, in FIG. 1B, channel A interface 125a of controller 121 is operatively coupled to CAA interface 115 and DQGRP1 interface 111. DQGRP2 interface 112. Channel B interface 126a of controller 121 is operatively coupled to CAB interface 116, DQGRP2 interface 112, and DQGRP3 interface 113. In FIG. 1B, channel A interface 125a of controller 121 has N₁ number of bidirectional data signals and channel B interface 126a of controller 121 has N₂+N₃ number of bidirectional data signals.

It should be understood from FIGS. 1A-1B that DQGRP1 111, DQGRP2 112, and DQGRP3 113 are non-overlapping sets of DQ signals where DQGRP2 112 may be configured to be part of a first memory channel (e.g., memory channel A—as illustrated in FIG. 1A) or to be part of a second memory channel (e.g., memory channel B—as illustrated in FIG. 1B). Thus, for example, if N₁=N₂=N₃=8, memory device 110 may be configured to interface with controller 121 which has a 16-bit DQ interface communicating via memory channel A and an 8-bit DQ interface communicating via memory channel B. Likewise, continuing the example with N₁=N₂=N₃=8, memory device 110 may be configured to interface with controller 122 which has an 8-bit DQ interface communicating via memory channel A and a 16-bit DQ interface communicating via memory channel B. Note that in both of these examples, the DQ width (i.e., number of DQ signals) of channel A and channel B are different (i.e., nonuniform).

In an embodiment, memory device 110 may also be configured such that memory channel A (via CAA interface 115) accesses a different numbers of memory arrays than memory channel B (via CAB interface 116). The number of memory arrays accessed via CAA interface 115 verses via CAB interface 116 may, in one example, be proportional to the number of DQ signal lines functioning as part of memory channel A verses the number of DQ signal lines functioning as part of memory channel B (e.g., memory channel A has 16 DQ signals and accesses 4 memory arrays 130a and memory channel B has 8 DQ signals and accesses 2 memory arrays 130b). In another example, the number of memory arrays accessed via CAA interface 115 verses via CAB interface 116 may not be proportional to the number of DQ signal lines functioning as part of memory channel A verses the number of DQ signal lines functioning as part of memory channel B (e.g., memory channel A has 16 DQ signals and accesses 4 memory arrays 130a and memory channel B has 8 DQ signals and accesses 6 memory arrays 130b).

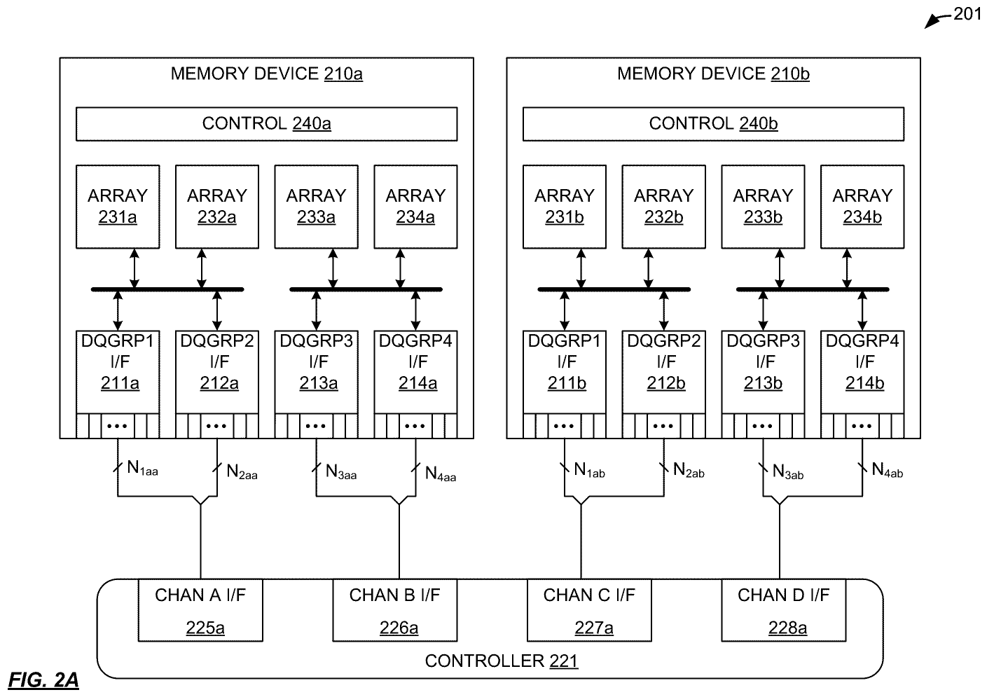

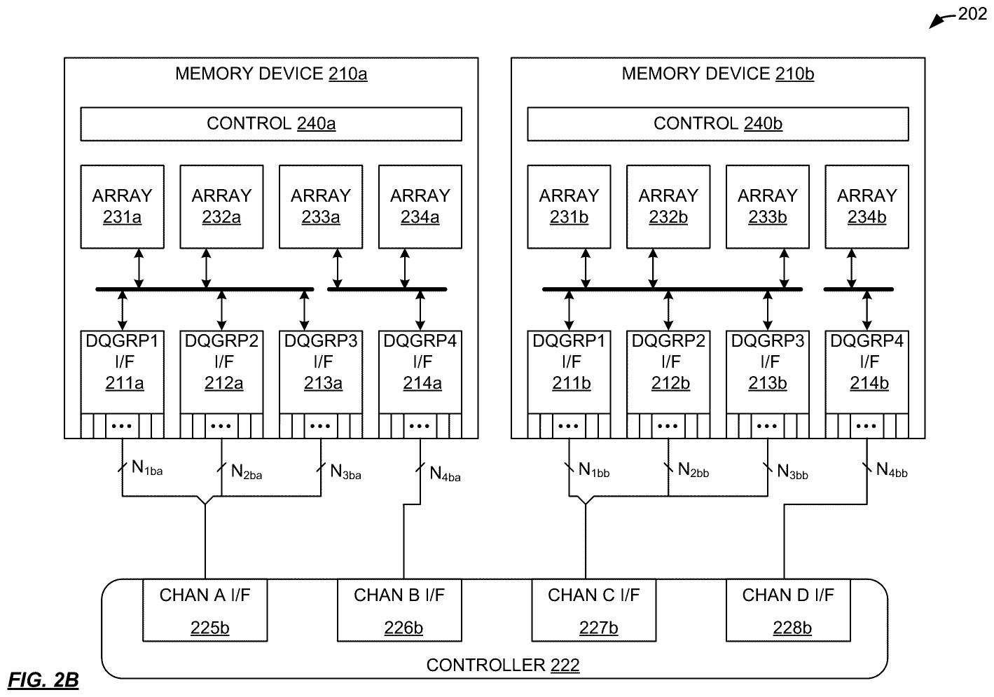

FIGS. 2A-2B are a block diagrams illustrating memory configurations. In FIGS. 2A-2B memory device 210a includes data (DQ) signal group #1 interface (DQGRP1 I/F 211a), DQ signal group #2 interface (DQGRP2 I/F 212a), DQ signal group #3 interface (DQGRP3 I/F 213a), DQ signal group #4 interface (DQGRP4 I/F 214a), memory arrays 231a-234a, and control circuitry 240a. Memory device 210a also includes two command/address interfaces (e.g., CAA I/F and CAB I/F) that are each part of a memory channel (e.g., memory channel A and memory channel B) that, for the sake of brevity, are not shown in FIGS. 2A-2B.

Memory device 210b includes data (DQ) signal group #1 interface (DQGRP1 I/F 211b), DQ signal group #2 interface (DQGRP2 I/F 212b), DQ signal group #3 interface (DQGRP3 I/F 213b), DQ signal group #4 interface (DQGRP4 I/F 214b), memory arrays 231b-234b, and control circuitry 240b. Memory device 210b also includes two command/address interfaces (e.g., CAA I/F and CAB I/F) that are each part of a memory channel (e.g., memory channel A and memory channel B) that, for the sake of brevity, are not shown in FIGS. 2A-2B. In an embodiment, memory device 210a and memory device 210b are identical but may be configured (e.g., by controller 221, control circuitry 240a, and/or control circuitry 240b) differently.

FIG. 2A illustrates a first memory system using a first configuration for memory devices 210a-210b. In FIG. 2A, memory system 201 comprises controller 221, memory device 210a, and memory device 210b. Controller 221 includes memory channel “A” 225a, memory channel “B” 226a, memory channel “C” 227a, and memory channel “D” 228a. Memory channel A 225a is operatively coupled to DQGRP1 interface 211a of memory device 210a using N₁ₐₐ number of data signals. Memory channel A 225a is operatively coupled to DQGRP2 interface 212a of memory device 210a using N₂ₐₐ number of data (DQ) signals. Thus, memory channel A 225a of controller 221 has N₁ₐₐ+N₂ₐₐ number of DQ signals.

Memory channel B 226a is operatively coupled to DQGRP3 interface 213a of memory device 210a using N₃ₐₐ number of data signals. Memory channel B 226a is operatively coupled to DQGRP4 interface 214a of memory device 210a using N₄ₐₐ number of data (DQ) signals. Memory channel A 226a is operatively coupled to DQGRP4 interface 214a of memory device 210a using N₄ₐₐ number of data (DQ) signals. Thus, memory channel B 226a of controller 221 has N₃ₐₐ+N₄ₐₐ number of DQ signals.

Memory channel C 227a is operatively coupled to DQGRP1 interface 211b of memory device 210b using N_{1ab} number of data signals. Memory channel C 227a is operatively coupled to DQGRP2 interface 212b of memory device 210b using N_{2ab} number of data (DQ) signals. Thus, memory channel C 227a of controller 221 has N_{1ab}+N_{2ab} number of DQ signals.

Memory channel D 228a is operatively coupled to DQGRP3 interface 213b of memory device 210b using N_{3ab} number of data signals. Memory channel D 228a is operatively coupled to DQGRP4 interface 214b of memory device 210b using N_{4ab} number of data (DQ) signals. Thus, memory channel D 228a of controller 221 has N_{3ab}+N_{4ab} number of DQ signals.

In FIG. 2A, memory device 210a is configured such that memory channel A 225a of controller 221 accesses memory arrays 231a-232a via DQGRP1 interface 211a and DQGRP2 interface 212a. Memory device 210a is also configured such that memory channel B 226a of controller 221 accesses memory arrays 233a-234a via DQGRP3 interface 213a and DQGRP4 interface 214a. Thus, memory device 210a is configured such that each of memory channel A 225a and memory channel B 226a access the same number of arrays/banks in memory device 210a.

Likewise, in FIG. 2A, memory device 210b is configured such that memory channel C 227a of controller 221 accesses memory arrays 231b-232b via DQGRP1 interface 211b and DQGRP2 interface 212b. Memory device 210b is also configured such that memory channel D 228a of controller 221 accesses memory arrays 233b-234b via DQGRP3 interface 213b and DQGRP4 interface 214b. Thus, memory device 210b is configured such that each of memory channel C 227a and memory channel D 228a access the same number of arrays/banks in memory device 210b.

In an embodiment, controller 221 and memory devices 210a-210b are configured such that memory channel A 225a, memory channel B 226a, memory channel C 227a, and memory channel D 228a each have the same number of data signals (e.g., 16-bits). Likewise, memory devices 210a-210b are configured such that DQGRP1 interface 211a, DQGRP2 interface 212a, DQGRP3 interface 213a, DQGRP4 interface 214a, DQGRP1 interface 211b, DQGRP2 interface 212b, DQGRP3 interface 213b, and DQGRP4 interface 214b each have the same number of data signals (e.g., 8-bits). In other words, in an embodiment, controller 221 and memory devices 210a-210b are configured such that N₁ₐₐ=N₂ₐₐ=N₃ₐₐ=N₄ₐₐ=N_{1ab}=N_{2ab}=N_{3ab}=N_{4ab}.

FIG. 2B illustrates a second memory system using a second configuration for memory devices 210a-210b. In FIG. 2B, memory system 202 comprises controller 222, memory device 210a, and memory device 210b. Controller 222 includes memory channel “A”225b, memory channel “B” 226b, memory channel “C” 227b, and memory channel “D” 228b. Memory channel A 225b is operatively coupled to DQGRP1 interface 211a of memory device 210a using N_{1ba} number of data (DQ) signals. Memory channel A 225b is operatively coupled to DQGRP2 interface 212a of memory device 210a using N_{2ba} number of DQ signals. Memory channel A 225a is operatively coupled to DQGRP3 interface 213a of memory device 210a using N_{3ba} number of DQ signals. Thus, memory channel A 225b of controller 222 has N_{1ba}+N_{2ba}+N_{3ba} number of DQ signals.

Memory channel B 226b is operatively coupled to DQGRP4 interface 214a of memory device 210a using N_{4ba} number of data signals. Thus, memory channel B 226b of controller 222 has N_{4ba} number of DQ signals.

Memory channel C 227b is operatively coupled to DQGRP1 interface 211b of memory device 210b using N_{1bb} number of data (DQ) signals. Memory channel C 227a is operatively coupled to DQGRP2 interface 212b of memory device 210b using N_{2bb} number of DQ signals. Memory channel C 227a is operatively coupled to DQGRP3 interface 213b of memory device 210b using N_{3bb} number of DQ signals. Thus, memory channel C 227a of controller 221 has N_{1bb}+N_{2bb}+N_{3bb} number of DQ signals.

Memory channel D 228b is operatively coupled to DQGRP4 interface 214b of memory device 210b using N_{4bb} number of data signals. Thus, memory channel D 228a of controller 221 has N_{4bb} number of DQ signals.

In FIG. 2B, memory device 210a is configured such that memory channel A 225b of controller 222 accesses memory arrays 231a-232a via DQGRP1 interface 211a, DQGRP2 interface 212a, and DQGRP3 interface 213a. Memory device 210a is also configured such that memory channel B 226b of controller 222 accesses memory arrays 233a-234a via DQGRP4 interface 214a. Thus, memory device 210a is configured such that each of memory channel A 225b and memory channel B 226b access the same number of arrays/banks in memory device 210a even though memory channel A 225b and memory channel B 226b may have different numbers of DQ signals (i.e., N_{1ba}+N_{2ba}+N_{3ba}≠N_{4ba}).

Also, in FIG. 2B, memory device 210b is configured such that memory channel C 227b of controller 222 accesses memory arrays 231b-233b via DQGRP1 interface 211b, DQGRP2 interface 212b, and DQGRP3 interface 213b. Memory device 210b is also configured such that memory channel D 228a of controller 222 accesses memory array 234b via DQGRP4 interface 214b. Thus, memory device 210b is configured such that each of memory channel C 227b and memory channel D 228b may each access numbers of arrays/banks in memory device 210b that may be proportional to the number of DQ signals in memory channel C 227b and memory channel D 228b (e.g., when N_{1bb}=N_{2bb}=N_{3bb}=N_{4bb} and memory arrays 231b-233b represent 6 memory arrays/banks and memory array 234b represents 2 memory arrays/banks).

In an embodiment, controller 222 and memory devices 210a-210b are configured such that memory channel A 225b and memory channel B 226b have different numbers of data signals (e.g., 24-bits and 8 bits, respectively). Likewise, in an embodiment, memory channel C 227b, and memory channel D 228b each have different numbers of data signals (e.g., 24-bits and 8 bits, respectively). Memory devices 210a-210b are configured such that DQGRP1 interface 211a, DQGRP2 interface 212a, DQGRP3 interface 213a, DQGRP4 interface 214a, DQGRP1 interface 211b, DQGRP2 interface 212b, DQGRP3 interface 213b, and DQGRP4 interface 214b each have the same number of data signals (e.g., 8-bits). In other words, in an embodiment, controller 221 and memory devices 210a-210b are configured such that N_{1ba}=N_{2ba}=N_{3ba}=N_{4ba}=N_{1bb}=N_{2bb}=N_{3bb}=N_{4bb}.

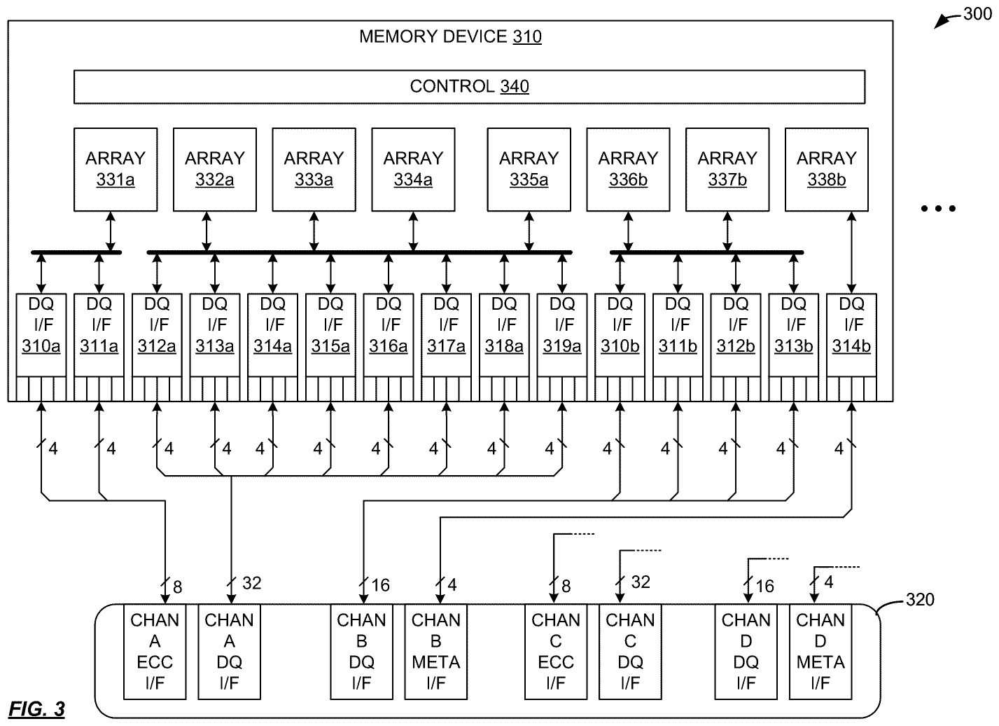

FIG. 3 is a block diagram illustrating an example system configuration with four channel configurable memory devices. In FIG. 3, memory system 300 comprises memory controller 320 and memory device 310. Memory controller 320 includes memory channel “A”, memory channel “B”, memory channel “C”, and memory channel “D”. Memory channel A includes 32 data signals assigned to communicate data and 8 data signals assigned to communicate error detect and correct (a.k.a., ECC) information. Memory channel B includes 16 data signals assigned to communicate data and 4 data signals assigned to communicate metadata. Memory channel C includes 32 data signals assigned to communicate data and 8 data signals assigned to communicate error detect and correct (a.k.a., ECC) information. Memory channel D includes 16 data signals assigned to communicate data and 4 data signals assigned to communicate metadata.

Memory device 310 comprises data signal group interfaces 310a-319a, data signal group interfaces 310b-314b, memory arrays 3310a-335a, memory arrays 336b-338b, and control circuitry 340. Each of the fifteen (15) data signal group interfaces 310a-319a and data signal group interfaces 310b-314b include 4 data signals for a total of sixty (60) DQ signals communicating with memory controller 320.

The 8 data signals of memory channel A of memory controller 320 allocated to communicate ECC data are operatively coupled to DQ interfaces 310a-311a of memory device 310. The 32 data signals of memory channel A of memory controller 320 allocated to communicate data are operatively coupled to DQ interfaces 312a-319a of memory device 310.

The 16 data signals of memory channel B of memory controller 320 allocated to communicate data are operatively coupled to DQ interfaces 310b-313b of memory device 310. The 4 data signals of memory channel B of memory controller 320 allocated to communicate metadata are operatively coupled to DQ interface 314b of memory device 310.

In an embodiment, memory device 310 is configured (e.g., by control circuitry 340) such that array 331a is accessed for ECC data communicated via DQ interfaces 310a-311a. Memory device 310 is also configured such that arrays 332a-335a are accessed for data communicated via DQ interfaces 312a-319a. Memory device 310 is also configured such that arrays 336b-337b are accessed for data communicated via DQ interfaces 310b-313b. Memory device 310 is configured such that array 338b is accessed for metadata communicated via DQ interface 314b.

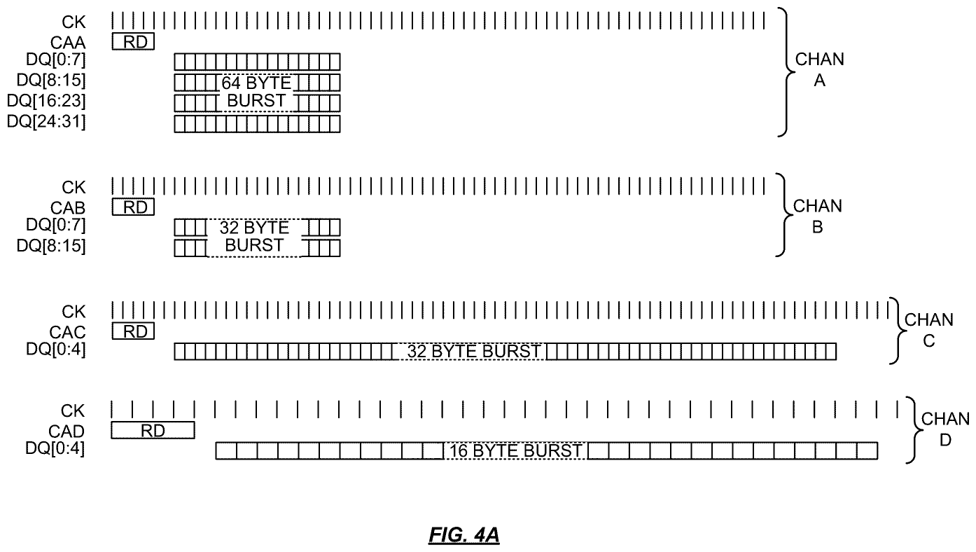

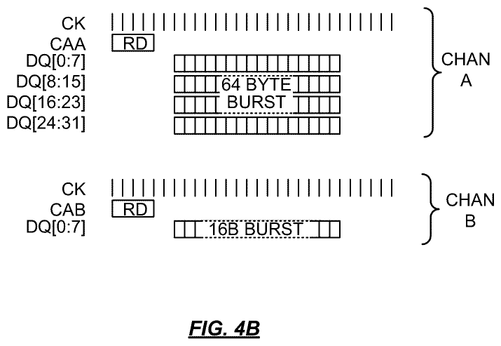

FIGS. 4A-4B are diagrams illustrating example data burst configurations for multi-channel memory devices. In FIG. 4A, memory channel “A” includes a timing signal (CK), command/address signals (CAA), and 32 data signals (shown in four bytes groups: DQ[0:7], DQ[8:15], DQ[16:23], and DQ[24:31]). FIG. 4A illustrates CAA signals issuing a read command (RD) over four clock cycles. Two clock cycles later, a 64 byte data burst occurs over 16 clock cycles on data signals DQ[0:31].

Also, in FIG. 4A, memory channel “B” includes a timing signal (CK), command/address signals (CAB), and 16 data signals (shown in two bytes groups: DQ[0:7], and DQ[8:15]). FIG. 4A illustrates CAB signals issuing a read command (RD) over four clock cycles. Two clock cycles later, a 32 byte data burst occurs over 16 clock cycles on data signals DQ[0:15]. Also, in FIG. 4A, memory channel “C” includes a timing signal (CK), command/address signals (CAC), and 4 data signals (shown in on 4-bit group: DQ[0:3]. FIG. 4A illustrates CAC signals issuing a read command (RD) over four clock cycles. Two clock cycles later, a 32 byte data burst occurs over 64 clock cycles on data signals DQ[0:3]. Also, in FIG. 4A, memory channel “D” includes a timing signal (CK), command/address signals (CAD), and 4 data signals (shown in on 4-bit group: DQ[0:3]. Timing signal CK of memory channel D is cycling at half (½) the frequency of the CK signals for memory channels A-C. FIG. 4A illustrates CAD signals issuing a read command (RD) over four (½ frequency) clock cycles. One clock cycles later, a 16 byte data burst occurs over 32 clock cycles on data signals DQ[0:3].

In FIG. 4B, memory channel “A” includes a timing signal (CK), command/address signals (CAA), and 32 data signals (shown in four bytes groups: DQ[0:7], DQ[8:15], DQ[16:23], and DQ[24:31]). FIG. 4B illustrates CAA signals issuing a read command (RD) over four clock cycles. Two clock cycles later, a 64 byte data burst occurs over 16 clock cycles on data signals DQ[0:31]. Also, in FIG. 4B, memory channel “B” includes a timing signal (CK), command/address signals (CAB), and 8 data signals (shown a single byte groups: DQ[0:7]). FIG. 4B illustrates CAB signals issuing a read command (RD) over four clock cycles. Two clock cycles later, a 16 byte data burst occurs over 16 clock cycles on data signals DQ[0:7].

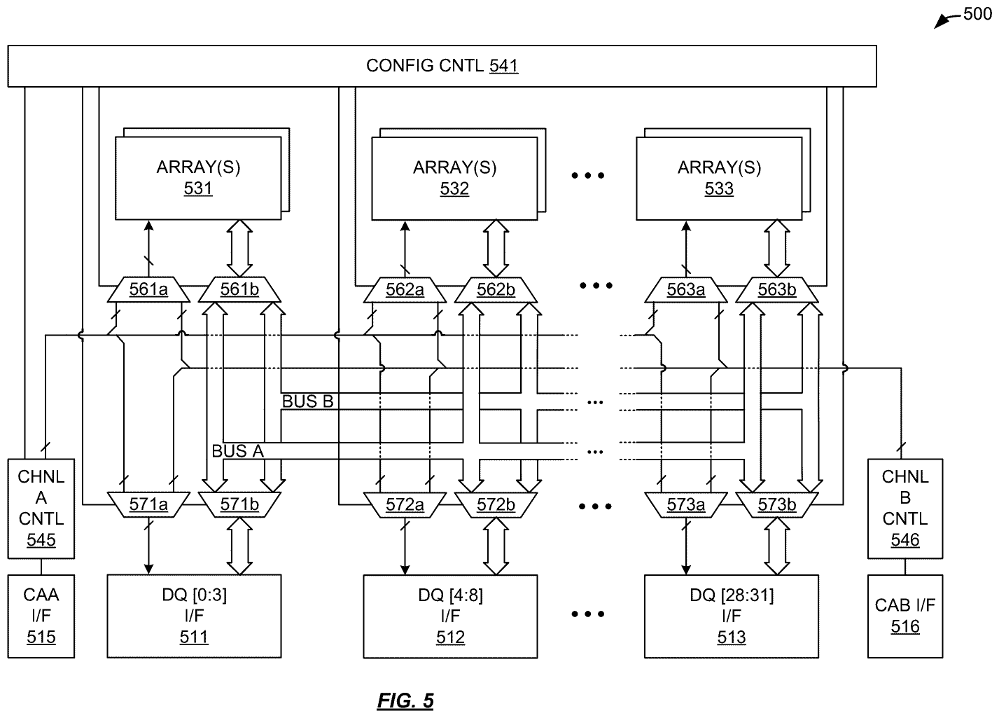

FIG. 5 is a block diagram illustrating a multi-channel memory device. In FIG. 5, memory device 500 comprises data group interfaces 511-513, command/address (CA) interface “A” 515 (i.e., command/address interface for memory channel “A”—a.k.a., CAA), CA interface “B” 516, memory arrays 531-533, configuration control circuitry 541, channel A control circuitry 545, channel B control circuitry 546, array control signal multiplexers (MUXs) 561a-563a, array data signal MUXs 561b-563b, interface control signal MUXs 571a-573a, and interface data signal MUXs 571b-573b.

The outputs of array control signal MUXs 561a-563a are operatively coupled to memory arrays 531-533, respectively. The inputs to array control signal MUXs 561a-563a are operatively coupled to channel A control circuitry 545 and channel B control circuitry 546, respectively. The outputs of array data signal MUXs 561b-563b are operatively coupled to memory arrays 531-533, respectively. The inputs to array control signal MUXs 561a-563a are operatively coupled to data bus A and data bus B, respectively. The outputs of interface control signal MUXs 571a-573a are operatively coupled to data group interfaces 511-513, respectively. The inputs to interface control signal MUXs 571a-573a are operatively coupled to channel A control circuitry 545 and channel B control circuitry 546, respectively. The outputs of interface data signal MUXs 571b-573b are operatively coupled to data group interfaces 511-513, respectively. The inputs to interface data signal MUXs 571b-573b are operatively coupled to data bus A and data bus B, respectively.

Array control signal MUXs 561a-563a select between memory array 531-533 control signals that are provided by channel A control circuitry 545 and channel B control circuitry 546. Array data signal MUXs 561b-563b select between two data busses of array data signals (bus A and bus B) that determine whether data to/from a given memory array 531-533 is to be accessed via memory channel A and memory channel B. Interface control signal MUXs 571a-573a select between interface control signals that are provided by channel A control circuitry 545 and channel B control circuitry 546. Interface data signal MUXs 571b-573b select between two data busses of array data signals (bus A and bus B) that determine whether data to/from a given data group interface 511-513 is to be accessed via bus A and bus B.

Configuration control circuitry 541 is operatively coupled to control the selected inputs of array control signal MUXs 561a-563a, array data signal MUXs 561b-563b, interface control signal MUXs 571a-573a, and interface data signal MUXs 571b-573b. Accordingly, configuration control may configure each of memory arrays 531-533 and each of data group interfaces 511-513 of memory device 510 to function as part of (or be accessed via) memory channel A and memory channel B. Thus, the memory capacity on each of memory channel A and memory channel B is configurable and may be nonuniformly allocated to different channels. In an embodiment, for a given configuration, an individual memory array 531-533 is only assigned to be accessed via a single channel. In addition, because the data signals of data group interfaces 511-513 may be allocated to different memory channels, the data width (i.e., number of DQ signals) on each of memory channel A and memory channel B is configurable and may be nonuniformly allocated to different channels. In particular, the number of DQ signals on a given channel may not be a power of two (e.g., 20, 24, etc.).

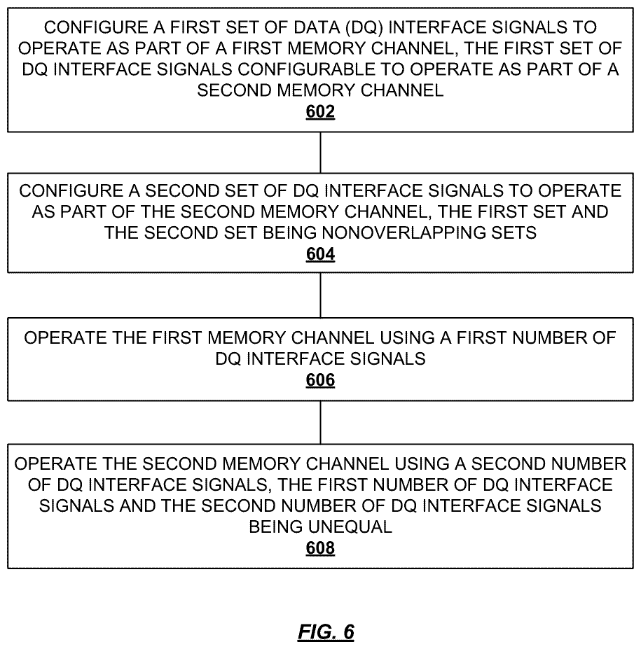

FIG. 6 is a flowchart illustrating a method of operating a memory device. One or more steps illustrated in FIG. 6 may be performed by, for example, memory system 101, memory system 102, memory system 201, memory system 202, memory system 300, memory device 500, and/or their components. A first set of data (DQ) interface signals are configured to operate as part of a first memory channel where the first set of DQ interface signals are configurable to operate as part of a second memory channel (602). For example, the signals of DQGRP2 interface 112 of memory device 110 may be configured to operate as part of controller 121's memory channel A 125a (as illustrated in FIG. 1A) where the signals of DQGRP2 interface 112 of memory device 110 could have been configured to operate as part of controller 121's memory channel B 126a (as illustrated in FIG. 1B).

A second set of DQ interface signals are configured to operate as part of the second memory channel where the first set and the second set are nonoverlapping sets (604). For example, the signals of DQGRP3 interface 113 of memory device 110 may be configured to operate as part of controller 121's memory channel B 126a (as illustrated in FIG. 1A). The first memory channel is operated using a first number of DQ interface signals (606). For example, controller 121's memory channel A 125a may be operated using N₁+N₂ number of data signals.

The second memory channel is operated using a second number of DQ interface signals where the first number of DQ interface signals and the second number of interface signals are unequal (608). For example, controller 121's memory channel B 126a may be operated using N₃ number of data signals, where N₁+N₂≠N₃.

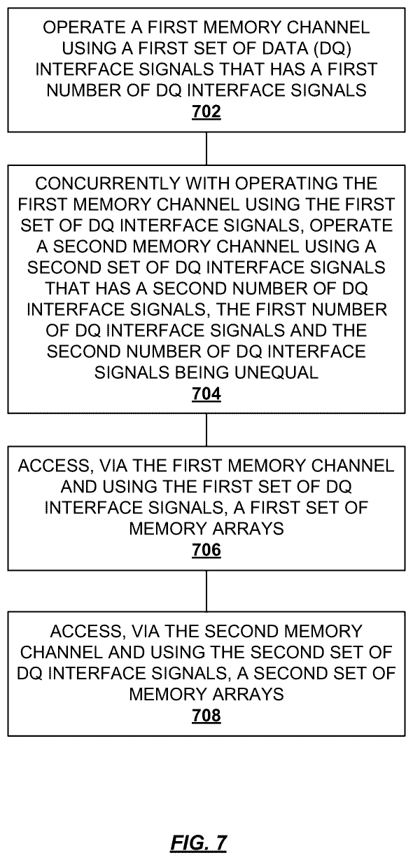

FIG. 7 is a flowchart illustrating a method of accessing a multi-channel memory device. One or more steps illustrated in FIG. 7 may be performed by, for example, memory system 101, memory system 102, memory system 201, memory system 202, memory system 300, memory device 500, and/or their components. A first memory channel is operated using a first set of data (DQ) interface signals that has a first number of DQ interface signals (702). For example, controller 121's memory channel A 125a may be operated by communicating with DQGRP1 interface 111 and DQGRP2 interface 112 of memory device 110 so that controller 121's memory channel A 125a is operated using N₁+N₂ number of data signals.

Concurrently with operating the first memory channel using the first set of DQ interface signals, a second memory channel is operated using a second set of DQ interface signals that has a second number of DQ interface signals where the first number of DQ interface signals and the second number of interface signals are unequal (704). For example, controller 121's memory channel B 126a may be operated by communicating with DQGRP3 interface 113 of memory device 110 so that controller 121's memory channel B 126a is operated using N₃ number of data signals, where N₁+N₂≠N₃.

Via the first memory channel and using the first set of DQ interface signals, a first set of memory arrays are accessed (706). For example, memory system 101 may be configured such that memory arrays 130a are accessed via controller 121's memory channel A 125a, DQGRP1 interface 111, and DQGRP2 interface 112. Via the second memory channel and using the second set of DQ interface signals, a second set of memory arrays are accessed (708). For example, memory system 101 may be configured such that memory arrays 130b are accessed via controller 121's memory channel B 126a and DQGRP3 interface 113.

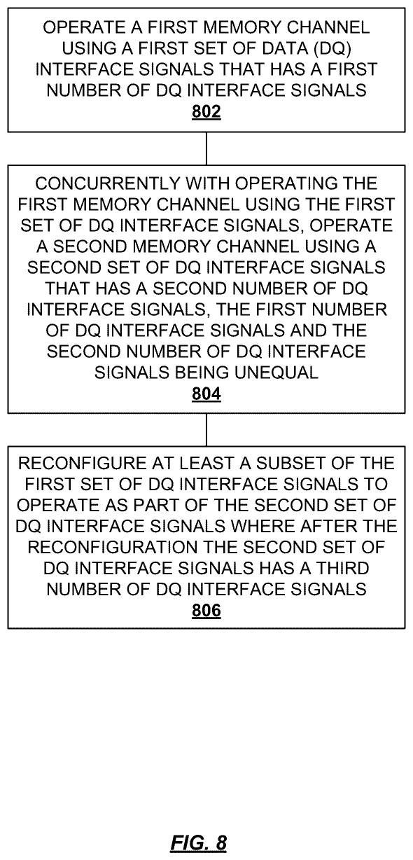

FIG. 8 is a flowchart illustrating a method of reconfiguring a multi-channel memory device. One or more steps illustrated in FIG. 8 may be performed by, for example, memory system 101, memory system 102, memory system 201, memory system 202, memory system 300, memory device 500, and/or their components. A first memory channel is operated using a first set of data (DQ) interface signals that has a first number of DQ interface signals (802). For example, controller 121's memory channel A 125a may be operated by communicating with DQGRP1 interface 111 and DQGRP2 interface 112 of memory device 110 so that controller 121's memory channel A 125a is operated using N1+N2 number of data signals.

Concurrently with operating the first memory channel using the first set of DQ interface signals, a second memory channel is operated using a second set of DQ interface signals that has a second number of DQ interface signals where the first number of DQ interface signals and the second number of interface signals are unequal (804). For example, controller 121's memory channel B 126a may be operated by communicating with DQGRP3 interface 113 of memory device 110 so that controller 121's memory channel B 126a is operated using N3 number of data signals, where N1+N2≠N3.

At least a subset of the first set of DQ interface signals are reconfigured to operate as part of the second set of DQ interface signals where after the reconfiguration the second set of DQ interface signals has a third number of DQ interface signals. For example, DQGRP2 interface 112 may be reconfigured to operate as part of memory channel B 126b such that memory channel B 126b is operated using N2+N3≠N1+N2.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of memory system 101, memory system 102, memory system 201, memory system 202, memory system 300, memory device 500, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3-½ inch floppy media, CDs, DVDs, and so on.

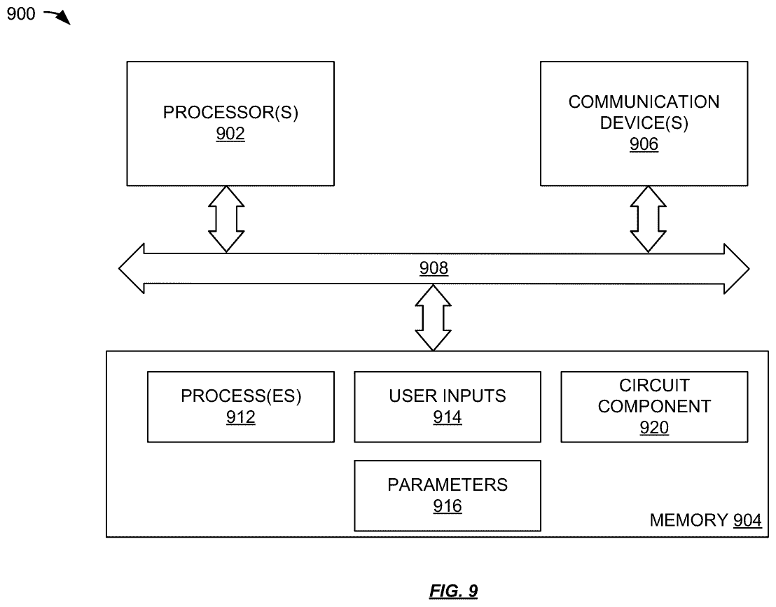

FIG. 9 is a block diagram illustrating one embodiment of a processing system 900 for including, processing, or generating, a representation of a circuit component 920. Processing system 900 includes one or more processors 902, a memory 904, and one or more communications devices 906. Processors 902, memory 904, and communications devices 906 communicate using any suitable type, number, and/or configuration of wired and/or wireless connections 908.

Processors 902 execute instructions of one or more processes 912 stored in a memory 904 to process and/or generate circuit component 920 responsive to user inputs 914 and parameters 916. Processes 912 may be any suitable electronic design automation (EDA) tool or portion thereof used to design, simulate, analyze, and/or verify electronic circuitry and/or generate photomasks for electronic circuitry. Representation 920 includes data that describes all or portions of memory system 101, memory system 102, memory system 201, memory system 202, memory system 300, memory device 500, and their components, as shown in the Figures.

Representation 920 may include one or more of behavioral, register transfer, logic component, transistor, and layout geometry-level descriptions. Moreover, representation 920 may be stored on storage media or communicated by carrier waves.

Data formats in which representation 920 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email

User inputs 914 may comprise input parameters from a keyboard, mouse, voice recognition interface, microphone and speakers, graphical display, touch screen, or other type of user interface device. This user interface may be distributed among multiple interface devices. Parameters 916 may include specifications and/or characteristics that are input to help define representation 920. For example, parameters 916 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 904 includes any suitable type, number, and/or configuration of non-transitory computer-readable storage media that stores processes 912, user inputs 914, parameters 916, and circuit component 920.

Communications devices 906 include any suitable type, number, and/or configuration of wired and/or wireless devices that transmit information from processing system 900 to another processing or storage system (not shown) and/or receive information from another processing or storage system (not shown). For example, communications devices 906 may transmit circuit component 920 to another system. Communications devices 906 may receive processes 912, user inputs 914, parameters 916, and/or circuit component 920 and cause processes 912, user inputs 914, parameters 916, and/or circuit component 920 to be stored in memory 904.

Implementations discussed herein include, but are not limited to, the following examples:

Example 1: A memory component, comprising: a plurality of command/address (CA) interfaces; and a plurality of data (DQ) interfaces each comprising a plurality of DQ signal groups, the memory component configurable to operate at least two CA interfaces in association with respective sets of DQ signal groups that are non-overlapping sets of DQ signal groups, to form respective memory channels, wherein at least two of the memory channels have different DQ signal widths, at least two of the plurality of DQ signal groups configurable to be operated as part of at least two of the respective memory channels.

Example 2: The memory component of example 1, further comprising: a plurality of memory arrays, the memory component configurable to have accesses to a first subset of the plurality of memory arrays occur via a first one of the respective memory channels, and configurable to have accesses to a second subset of the plurality of memory arrays to occur via a second one of the respective memory channels, the first subset and the second subset to have unequal storage capacity.

Example 3: The memory component of example 2, wherein each of the plurality of memory arrays are to only be accessed via one of the respective memory channels.

Example 4: The memory component of example 3, wherein the plurality of memory arrays are disposed on multiple identical integrated circuit die.

Example 5: The memory component of example 1, wherein at least two of the respective memory channels are configurable to be operated at different clock frequencies.

Example 6: The memory component of example 1, wherein at least two of the respective memory channels are configurable to be operated using different data block sizes.

Example 7: The memory component of example 1, wherein at least two of the respective memory channels are configurable to be operated using different numbers of unit intervals to communicate data bursts.

Example 8: A memory component, comprising: a first command/address (CA) interface to communicate commands and addresses as part of a first memory channel; a second CA interface to communicate commands and addresses as part of a second memory channel; and a plurality of data (DQ) interfaces each comprising a plurality of DQ signal groups, the memory component configurable to operate a first set of DQ signal groups as part of the first memory channel, the memory component configurable to operate the first set of DQ signal groups as part of the first memory channel, the memory component configurable to operate a second set of DQ signal groups as part of the second memory channel, where the memory component is configurable to have a first number of DQ signals operating as part of the first memory channel and a second number of DQ signals operating as part of the second memory channel where the first number and the second number are not equal, the first set and the second set to be proper subsets of the plurality of DQ signal groups.

Example 9: The memory component of example 8, further comprising: a plurality of memory arrays, the memory component configurable to have accesses to a first subset of the plurality of memory arrays occur via the first memory channel, and configurable to have accesses to a second subset of the plurality of memory arrays occur via the second memory channel, the first subset and the second subset to have unequal storage capacity.

Example 10: The memory component of example 9, wherein each of the plurality of memory arrays are to only be accessed via one of the first memory channel and the second memory channel.

Example 11: The memory component of example 9, wherein the plurality of memory arrays are disposed on a plurality of integrated circuit die.

Example 12: The memory component of example 8, wherein the memory component is configurable to operate the first memory channel to communicate bursts of data using a first number of unit intervals, and is configurable to operate the first memory channel to communicate bursts of data using a second number of unit intervals, where the first number of unit intervals and the second number of unit intervals are unequal.

Example 13: The memory component of example 8, wherein the memory component is configurable to have the first number not be a positive integer power of two.

Example 14: The memory component of example 8, wherein the memory component is configurable to operate the second set of DQ signal groups as part of the first memory channel.

Example 15: The memory component of example 14, wherein the memory component is configurable to disable the second CA interface.

Example 16: A method of operating a memory component, comprising: configuring a first set of data (DQ) interface signals to operate as part of a first memory channel, the first set of DQ interface signals configurable to operate as part of a second memory channel; configuring a second set of DQ interface signals to operate as part of the second memory channel, the first set and the second set being nonoverlapping sets; operating the first memory channel using a first number of DQ interface signals; and operating the second memory channel using a second number of DQ interface signals, the first number of DQ interface signals and the second number of DQ interface signals being unequal.

Example 17: The method of example 16, further comprising: accessing, via the first memory channel and using the first set of DQ interface signals, a first set of memory arrays; and accessing, via the second memory channel and using the second set of DQ interface signals, a second set of memory arrays.

Example 18: The method of example 17, wherein the first set of memory arrays and the second set of memory arrays are non-overlapping sets.

Example 19: The method of example 18, wherein the first set of memory arrays and the second set of memory arrays are disposed on different integrated circuit die.

Example 20: The method of example 16, further comprising: configuring the first set of DQ interface signals to operate as part of the second memory channel.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A memory component, comprising:
a plurality of command/address (CA) interfaces; and
a plurality of data (DQ) interfaces each comprising a plurality of DQ signal groups, the memory component configurable to operate at least two CA interfaces in association with respective sets of DQ signal groups that are non-overlapping sets of DQ signal groups, to form respective memory channels, wherein at least two of the memory channels have different DQ signal widths, at least two of the plurality of DQ signal groups configurable to be operated as part of at least two of the respective memory channels.

2. The memory component of claim 1, further comprising:
a plurality of memory arrays, the memory component configurable to have accesses to a first subset of the plurality of memory arrays occur via a first one of the respective memory channels, and configurable to have accesses to a second subset of the plurality of memory arrays to occur via a second one of the respective memory channels, the first subset and the second subset to have unequal storage capacity.

3. The memory component of claim 2, wherein each of the plurality of memory arrays are to only be accessed via one of the respective memory channels.

4. The memory component of claim 3, wherein the plurality of memory arrays are disposed on multiple identical integrated circuit die.

5. The memory component of claim 1, wherein at least two of the respective memory channels are configurable to be operated at different clock frequencies.

6. The memory component of claim 1, wherein at least two of the respective memory channels are configurable to be operated using different data block sizes.

7. The memory component of claim 1, wherein at least two of the respective memory channels are configurable to be operated using different numbers of unit intervals to communicate data bursts.

8. A memory component, comprising:
a first command/address (CA) interface to communicate commands and addresses as part of a first memory channel;
a second CA interface to communicate commands and addresses as part of a second memory channel; and
a plurality of data (DQ) interfaces each comprising a plurality of DQ signal groups, the memory component configurable to operate a first set of DQ signal groups as part of the first memory channel, the memory component configurable to operate the first set of DQ signal groups as part of the first memory channel, the memory component configurable to operate a second set of DQ signal groups as part of the second memory channel, where the memory component is configurable to have a first number of DQ signals operating as part of the first memory channel and a second number of DQ signals operating as part of the second memory channel where the first number and the second number are not equal, the first set and the second set to be proper subsets of the plurality of DQ signal groups.

9. The memory component of claim 8, further comprising:
a plurality of memory arrays, the memory component configurable to have accesses to a first subset of the plurality of memory arrays occur via the first memory channel, and configurable to have accesses to a second subset of the plurality of memory arrays occur via the second memory channel, the first subset and the second subset to have unequal storage capacity.

10. The memory component of claim 9, wherein each of the plurality of memory arrays are to only be accessed via one of the first memory channel and the second memory channel.

11. The memory component of claim 9, wherein the plurality of memory arrays are disposed on a plurality of integrated circuit die.

12. The memory component of claim 8, wherein the memory component is configurable to operate the first memory channel to communicate bursts of data using a first number of unit intervals, and is configurable to operate the first memory channel to communicate bursts of data using a second number of unit intervals, where the first number of unit intervals and the second number of unit intervals are unequal.

13. The memory component of claim 8, wherein the memory component is configurable to have the first number not be a positive integer power of two.

14. The memory component of claim 8, wherein the memory component is configurable to operate the second set of DQ signal groups as part of the first memory channel.

15. The memory component of claim 14, wherein the memory component is configurable to disable the second CA interface.

16. A method of operating a memory component, comprising:
configuring a first set of data (DQ) interface signals to operate as part of a first memory channel, the first set of DQ interface signals configurable to operate as part of a second memory channel;
configuring a second set of DQ interface signals to operate as part of the second memory channel, the first set and the second set being nonoverlapping sets;
operating the first memory channel using a first number of DQ interface signals; and
operating the second memory channel using a second number of DQ interface signals, the first number of DQ interface signals and the second number of DQ interface signals being unequal.

17. The method of claim 16, further comprising:
accessing, via the first memory channel and using the first set of DQ interface signals, a first set of memory arrays; and
accessing, via the second memory channel and using the second set of DQ interface signals, a second set of memory arrays.

18. The method of claim 17, wherein the first set of memory arrays and the second set of memory arrays are non-overlapping sets.

19. The method of claim 18, wherein the first set of memory arrays and the second set of memory arrays are disposed on different integrated circuit die.

20. The method of claim 16, further comprising:
configuring the first set of DQ interface signals to operate as part of the second memory channel.
